(19) United States
(12) Patent Application Publication
(10) Pub. No.: US 2024/0178122 A1
(43) Pub. Date: May 30, 2024

(54) SEMICONDUCTOR PACKAGE

(71) Applicant: SAMSUNG ELECTRONICS CO., LTD., Suwon-si (KR)

(72) Inventors: Kyung Don MUN, Suwon-si (KR); Sangjin BAEK, Suwon-si (KR); Kyoung Lim SUK, Suwon-si (KR); Shang-Hoon SEO, Suwon-si (KR); Inhyung SONG, Suwon-si (KR); Yeonho JANG, Suwon-si (KR)

(21) Appl. No.: 18/226,352

(22) Filed: Jul. 26, 2023

(30) Foreign Application Priority Data
Nov. 30, 2022 (KR) 10-2022-0164967

(51) Int. Cl. H01L 23/498; H01L 23/00; H01L 23/31; H01L 25/10

(52) U.S. Cl. CPC H01L 23/49838; H01L 23/3128; H01L 23/49816; H01L 23/49822; H01L 23/49833; H01L 24/16; H01L 25/105; H01L 2224/16227; H01L 2225/1023; H01L 2225/1041; H01L 2225/1058; H01L 2225/1094; H01L 2924/15311

(57) ABSTRACT

A semiconductor package, including a first redistribution substrate, a semiconductor chip on the first redistribution substrate, a connection structure on the first redistribution substrate and spaced apart from the semiconductor chip, the connection structure including a connection substrate and a post on the connection substrate, a second redistribution substrate on the semiconductor chip and the connection structure, and a molding layer between the first redistribution substrate and the second redistribution substrate, the molding layer encapsulating the semiconductor chip and the connection structure, wherein the connection substrate includes a conductive pattern that vertically penetrates the connection substrate, the post is in contact with a top surface of the conductive pattern, and a width of the post is less than a width of the connection substrate.

### CROSS-REFERENCE TO RELATED APPLICATION

Korean Patent Application No. 10-2022-0164967, filed on Nov. 30, 2022, in the Korean Intellectual Property Office, is hereby incorporated by reference in its entirety.

### BACKGROUND

### 1 Field

A semiconductor package is disclosed.

### 2. DESCRIPTION OF THE RELATED ART

A semiconductor package is provided to implement an integrated circuit chip to qualify for use in electronic products.

### SUMMARY

Embodiments are directed to a semiconductor package, including a first redistribution substrate, a semiconductor chip on the first redistribution substrate, a connection structure on the first redistribution substrate and spaced apart from the semiconductor chip, the connection structure including a connection substrate and a post on the connection substrate, a second redistribution substrate on the semiconductor chip and the connection structure, and a molding layer between the first redistribution substrate and the second redistribution substrate, the molding layer encapsulating the semiconductor chip and the connection structure, wherein the connection substrate includes a conductive pattern that vertically penetrates the connection substrate, the post is in contact with a top surface of the conductive pattern, and a width of the post is less than a width of the connection substrate.

Embodiments are directed to a semiconductor package, including a first redistribution substrate, a semiconductor chip on the first redistribution substrate, a second redistribution substrate on the semiconductor chip, a connection structure spaced apart from the semiconductor chip and connecting the first redistribution substrate and the second redistribution substrate to each other, the connection structure including a connection substrate and a post on the connection substrate, and a molding layer between the first redistribution substrate and the second redistribution substrate, the molding layer surrounding the post and the semiconductor chip, wherein the connection substrate includes a core layer, a first conductive pattern that vertically penetrates the core layer, an upper layer that covers a top surface of the core layer, a lower layer that covers a bottom surface of the core layer, and a plurality of second conductive patterns that penetrate the upper layer and the lower layer, the plurality of second conductive patterns being connected to the first conductive pattern, each of the plurality of second conductive patterns having a width that decreases with distance from the core layer.

Embodiments are directed to a semiconductor package, including a first redistribution substrate, a first semiconductor chip mounted on the first redistribution substrate, a connection substrate on the first redistribution substrate and surrounding the first semiconductor chip, a post on the connection substrate, a molding layer that surrounds the first semiconductor chip, the post, and the connection substrate, and a second redistribution substrate on the molding layer, wherein the connection substrate includes a core layer, an upper layer on a top surface of the core layer, a lower layer on a bottom surface of the core layer, a first conductive pattern that vertically penetrates the core layer, and a plurality of second conductive patterns that correspondingly penetrate the upper layer and the lower layer, a lateral surface of the core layer, a lateral surface of the upper layer, and a lateral surface of the lower layer being vertically aligned with each other, and a width of the first conductive pattern being constant between the top surface and the bottom surface of the core layer.

### BRIEF DESCRIPTION OF THE DRAWINGS

Features will become apparent to those of skill in the art by describing in detail exemplary embodiments with reference to the attached drawings in which:

FIG. 1 is a cross-sectional view showing a semiconductor package.

FIG. 2 is an enlarged view showing section A of FIG. 1.

FIG. 3 is a cross-sectional view showing a semiconductor package.

FIG. 4 is an enlarged view showing section B of FIG. 2.

FIG. 5 is a cross-sectional view showing a semiconductor package.

FIGS. 6 to 11 are cross-sectional views showing steps in a method of fabricating a semiconductor package.

### DETAILED DESCRIPTION

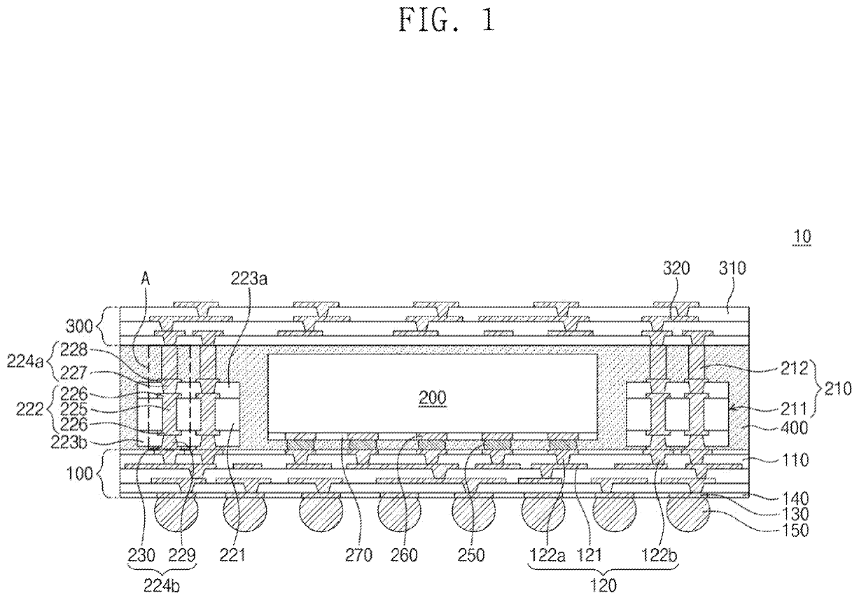

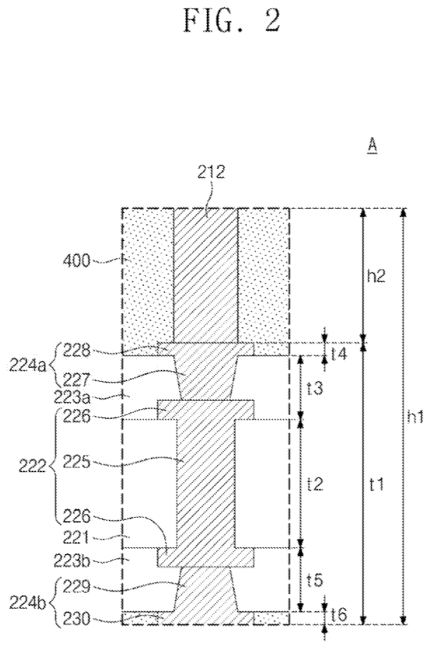

FIG. 1 is a cross-sectional view showing a semiconductor package. FIG. 2 is an enlarged view showing section A of FIG. 1.

Referring to FIGS. 1 and 2, a semiconductor package 10 may include a first redistribution substrate 100, a first semiconductor chip 200, a connection structure 210, a second redistribution substrate 300, and a first molding layer 400.

The first redistribution substrate 100 may include a plurality of first dielectric layers 110 that are stacked on each other. FIG. 1 depicts that three first dielectric layers 110 are stacked. The number of the first dielectric layers 110 stacked on the first redistribution substrate 100 may be variously changed if necessary. The first dielectric layer 110 may include an organic material, such as a photo-imageable dielectric (PID) material. The photo-imageable dielectric may be a polymer. The photo-imageable dielectric material may include, e.g., photosensitive polyimide, polybenzoxazole, phenolic polymers, or benzocyclobutene polymers. FIG. 1 shows a boundary between the first dielectric layers 110. According to some embodiments, an indistinct interface may be between neighboring first dielectric layers 110. As used herein, the term “or” is not an exclusive term, e.g., “A or B” would include A, B, or A and B.

The first dielectric layers 110 may be provided with first redistribution patterns 120 therein. The first redistribution patterns 120 may each have a first via part and a first line part that may be connected into a single unitary piece. The first line part may be a pattern for horizontal connection in the first redistribution substrate 100. The first via part may be a portion for vertical connection between the first redistribution patterns 120 in the first dielectric layers 110. The first line part may be on the first via part. The first line part and the first via part may be connected with no interface therebetween. The first line part may have a width greater than that of the first via part. In an implementation, the first via part may have a first via part upper width at an upper portion of the first via part and a first via part lower width at a lower portion of the first via part, and the first via part upper width may be greater than the first via part lower width. In greater detail, the first via part may have a width that decreases with distance from the top surface of the first via part. In an implementation, both the first via part upper width and the first via part lower width may be smaller than the width of the first line part.

In an implementation, each of the first redistribution patterns 120 may have a T shape when viewed in vertical section. The first line parts of the first redistribution patterns 120 may be positioned on top surfaces of the first dielectric layers 110. The first via parts of the first redistribution patterns 120 may penetrate the first dielectric layers 110 coupled to the first line parts of other first redistribution patterns 120 that underlie the first via parts of the first redistribution patterns 120. The first redistribution patterns 120 may include a conductive material. In an implementation, the first redistribution patterns 120 may include copper (Cu).

Seed patterns may be on bottom surfaces of the first redistribution patterns 120. In an implementation, the seed patterns may cover bottom surfaces and sidewalls of the first via parts included in corresponding first redistribution patterns 120, and may also cover bottom surfaces of the first line parts included in corresponding first redistribution patterns 120. The seed patterns may include a different material from that of the first redistribution patterns 120. In an implementation, the seed patterns may include an alloy such as copper (Cu) or titanium (Ti). The first redistribution patterns 120 may further include a barrier layer that prevents diffusion of materials included in the first redistribution patterns 120. The barrier layer may include titanium nitride (TiN) or tantalum nitride (TaN).

The first redistribution patterns 120 may include first wiring patterns 121 and first redistribution pads 122a and 122b. The first redistribution pads 122a and 122b may be a portion of the first redistribution pattern 120 on top of the first redistribution substrate 100. In an implementation, the first redistribution pads 122a and 122b may be the first redistribution patterns 120 exposed on a top surface of the first redistribution substrate 100. The first redistribution pads 122a and 122b may be coupled to the first wiring patterns 121 thereunder. The first redistribution patterns 120 may be a wiring pattern that may be electrically connected to the first semiconductor chip 200 so as to redistribute the first semiconductor chip 200.

Substrate pads 130 may be below a lowermost one of the first dielectric layers 110. The substrate pads 130 may be laterally spaced apart from each other. The substrate pads 130 may be connected to the first redistribution patterns 120. In an implementation, the first via part of a lowermost one of the first redistribution patterns 120 may penetrate the first dielectric layer 110 connected to the substrate pad 130. The substrate pads 130 may be electrically connected through the first wiring patterns 121 to the first redistribution pads 122a and 122b. The substrate pads 130 may include a conductive material. In an implementation, the substrate pads 130 may include copper (Cu).

A substrate protection layer 140 may be below the lowermost first dielectric layer 110. The substrate protection layer 140 may surround the substrate pads 130 on a bottom surface of the lowermost first dielectric layer 110. The substrate protection layer 140 may expose bottom surfaces of the substrate pads 130. The substrate protection layer 140 may include a solder resist (i.e., a solder mask) material.

The first redistribution substrate 100 may be provided with first connection terminals 150 on a bottom surface thereof. The first connection terminals 150 may be on the bottom surfaces of the substrate pads 130. The first connection terminals 150 may be laterally spaced apart from each other. The first connection terminals 150 may include a solder material. In an implementation, the first connection terminals 150 may include an alloy including tin (Sn), bismuth (Bi), lead (Pb), or silver (Ag).

The first semiconductor chip 200 may be on the first redistribution substrate 100. The first semiconductor chip 200 may be, e.g., a logic chip or a buffer chip. The logic chip may include an applicant specific integrated circuit (ASIC) chip or an application processor (AP) chip. Alternatively, the logic chip may include a central processing unit (CPU) or a graphic processing unit (GPU). The ASIC chip may include an application specific integrated circuit (ASIC). For another example, the first semiconductor chip 200 may be a memory chip.

The first semiconductor chip 200 may have first chip pads 260 on a bottom surface thereof. The first chip pads 260 may be electrically connected to an integrated circuit in the first semiconductor chip 200. The first chip pads 260 may be exposed on the bottom surface of the first semiconductor chip 200. The first chip pads 260 may include a conductive material. The first chip pads 260 may include, e.g., copper (Cu).

A chip passivation layer 270 may be on the bottom surface of the first semiconductor chip 200. The chip passivation layer 270 may surround the first chip pads 260. The chip passivation layer 270 may not cover the first chip pads 260 and may expose bottom surfaces of the first chip pads 260. The chip passivation layer 270 may have a bottom surface coplanar with those of the first chip pads 260. The chip passivation layer 270 may include a dielectric material, such as silicon oxide (SiO), silicon nitride (SiN), or silicon carbonitride (SiCN).

The first semiconductor chip 200 may be mounted on the first redistribution substrate 100. The first semiconductor chip 200 may be mounted in a flip-chip manner. In an implementation, first chip connection terminals 250 may be between the first semiconductor chip 200 and the first redistribution substrate 100. The first chip connection terminals 250 may be between the first chip pads 260 of the first semiconductor chip 200 and the first redistribution pads 122a of the first redistribution substrate 100. The first chip connection terminals 250 may be coupled to the first chip pads 260 of the first semiconductor chip 200 and the first redistribution pads 122a of the first redistribution substrate 100. Therefore, the first semiconductor chip 200 may be electrically connected through the first chip connection terminals 250 to the first redistribution patterns 120 of the first redistribution substrate 100. The first chip connection terminals 250 may include a conductive material. The first chip connection terminals 250 may include, e.g., copper (Cu).

One or more connection structures 210 may be on the first redistribution substrate 100. The connection structures 210 may be on the first redistribution pad 122b of the first redistribution substrate 100. The connection structures 210 may be between a lateral surface of the first redistribution substrate 100 and a lateral surface of the first semiconductor chip 200. In an implementation, the connection structures 210 may be above the first redistribution pads 122b. The connection structures 210 may be spaced apart from the first semiconductor chip 200. The connection structures 210 may surround the first semiconductor chip 200. In an implementation, the connection structures 210 may be arranged along the lateral surface of the first semiconductor chip 200. A planar arrangement of the connection structures 210 may be variously changed. The connection structures 210 may be a vertical connection structure provided for electrical connection between the first redistribution substrate 100 and the second redistribution substrate 300 which will be discussed below. This will be further discussed in detail below. Each of the connection structures 210 may have a height h1 of about 400 μm to about 600 μm.

Each of the connection structures 210 may include a connection substrate 211 and posts 212. The following will focus on one connection structure 210 for explaining a configuration of the connection structures 210.

The connection substrate 211 may include a core layer 221, a first conductive pattern 222, an upper layer 223a, a lower layer 223b, and second conductive patterns 224a and 224b. The connection substrate 211 may have a thickness t1 of about 350 μm to about 550 μm.

The core layer 221 may include a dielectric material. The dielectric material may include a thermosetting resin such as epoxy resin, a thermoplastic resin such as polyimide, or a resin in which a thermosetting or thermoplastic resin is impregnated with a reinforcement such as glass fiber and/or inorganic filler (which impregnated resin includes a prepreg, Ajinomoto build-up film (AFB), a fire resist-4 (FR4), or bismaleimide triazine (BT)). The core layer 221 may have a thickness t2 of about 150 μm to about 250 μm.

The first conductive pattern 222 may vertically penetrate the core layer 221. In an implementation, a first via 225 of the first conductive pattern 222 may vertically penetrate the core layer 221. The first via 225 may be surrounded by the core layer 221. The first via 225 may have a width that is constant from top to bottom surfaces of the core layer 221. In this description, a width may mean a width in a direction parallel to the first redistribution substrate 100.

The first conductive pattern 222 may have first pads 226 on top and bottom surfaces of the first via 225. Each of the first pads 226 may be in contact with one of the top and bottom surfaces of the first via 225. The first pads 226 may protrude from the core layer 221. In an implementation, each of the first pads 226 may be positioned on one of the top and bottom surfaces of the core layer 221. The first pads 226 may be connected through the first via 225 to each other. An invisible interface may be between the first via 225 and the first pads 226.

The upper layer 223a may be on the top surface of the core layer 221. The upper layer 223a may cover the first pad 226 and the top surface of the core layer 221. A lateral surface of the upper layer 223a may be vertically aligned with that of the core layer 221. The upper layer 223a may have a thickness t3 of about 80 μm to about 120 μm. The upper layer 223a may include a material the same as or similar to that of the core layer 221.

A second upper conductive pattern 224a may penetrate the upper layer 223a. In an implementation, the second upper conductive pattern 224a may have a second upper via 227 that may penetrate the upper layer 223a. The second upper via 227 may be surrounded by the upper layer 223a. The second upper via 227 may have a width that decreases with distance from the top surface of the core layer 221. A bottom surface of the second upper via 227 may be in contact with the first pad 226 on the top surface of the core layer 221. In an implementation, the second upper conductive pattern 224a may be coupled to the first conductive pattern 222.

The second upper conductive pattern 224a may have a second upper pad 228 on a top surface of the second upper via 227. The second upper pad 228 may be in contact with the top surface of the second upper via 227. The second upper pad 228 may protrude from the upper layer 223a. In an implementation, the second upper pad 228 may be positioned on a top surface of the upper layer 223a. An invisible interface may be between the second upper pad 228 and the second upper via 227. The second upper pad 228 may have a thickness t4 of about 10 μm to about 30 μm.

The lower layer 223b may be on the bottom surface of the core layer 221. The lower layer 223b may cover the first pad 226 and the bottom surface of the core layer 221. In an implementation, the core layer 221 may be between the upper layer 223a and the lower layer 223b. A lateral surface of the lower layer 223b may be vertically aligned with that of the core layer 221. The lower layer 223b may have a thickness t5 of about 80 μm to about 120 μm. The lower layer 223b may include a material the same as or similar to that of the core layer 221.

A second lower conductive pattern 224b may penetrate the lower layer 223b. In an implementation, the second lower conductive pattern 224b may have a second lower via 229 that may penetrate the lower layer 223b. The second lower via 229 may be surrounded by the lower layer 223b. The second lower via 229 may have a width that decreases with distance from the bottom surface of the core layer 221. A top surface of the second lower via 229 may be in contact with the first pad 226 on the bottom surface of the core layer 221. In an implementation, the second lower conductive pattern 224b may be coupled to the first conductive pattern 222. The second lower conductive pattern 224b may be connected through the first conductive pattern 222 to the second upper conductive pattern 224a.

The second lower conductive pattern 224b may have a second lower pad 230 on a bottom surface of the second lower via 229. The second lower pad 230 may protrude from the lower layer 223b. In an implementation, the second lower pad 230 may be positioned on a bottom surface of the lower layer 223b. An invisible interface may be between the second lower pad 230 and the second lower via 229. A bottom surface of the second lower pad 230 may be in contact with the first redistribution pad 122b of the first redistribution substrate 100. The second lower pad 230 may have a thickness t6 of about 10 μm to about 30 μm.

FIGS. 1 and 2 show that one upper layer 223a and one lower layer 223b may be on the core layer 221. According to some embodiments, two or more upper layers 223a may be on the top surface of the core layer 221, or two or more lower layers 223b may be on the bottom surface of the core layer 221. In this case, a certain second upper conductive pattern 224a of one of the upper layers 223a may be electrically connected to another second upper conductive pattern 224a of a different upper layer 223a that underlies the certain second upper conductive pattern 224a, and a certain second lower conductive pattern 224b of one of the lower layers 223b may be electrically connected to another second lower conductive pattern 224b of a different lower layer 223b that underlies the certain second lower conductive pattern 224b. The following description will focus on the embodiment of FIGS. 1 and 2.

The posts 212 may be on the connection substrate 211. The posts 212 may be on the second upper pad 228. A bottom surface of each of the posts 212 may be in contact with a top surface of the second upper pad 228. The posts 212 may be electrically connected to the second upper conductive pattern 224a. The posts 212 may be spaced apart from the core layer 221, the upper layer 223a, and the lower layer 223b. The posts 212 may not be in direct contact with any of the core layer 221, the upper layer 223a, and the lower layer 223b. The posts 212 may connect the connection substrate 211 to the second redistribution substrate 300. Each of the posts 212 may have a width less than that of the connection substrate 211. The posts 212 may each have a vertical height h2 less than a vertical height of the connection substrate 211. The vertical height of the connection substrate 211 may correspond to the thickness t1 of the connection substrate 211. The vertical height h2 of each of the posts 212 may range from about 50 μm to about 70 μm. The posts 212 may include a conductive material. The posts 212 may include, e.g., copper (Cu).

The first molding layer 400 may be on the first redistribution substrate 100. On the first redistribution substrate 100, the first molding layer 400 may surround the first semiconductor chip 200 and the connection structures 210. The first molding layer 400 may surround the first semiconductor chip 200, and may also surround the posts 212 and the connection substrate 211 of the connection structure 210. The first molding layer 400 may encapsulate the first semiconductor chip 200, the posts 212, and the connection substrate 211. The first molding layer 400 may surround the first chip connection terminals 250 between the first redistribution substrate 100 and the first semiconductor chip 200. Alternatively, an underfill material may fill a space between the first redistribution substrate 100 and the first semiconductor chip 200. A lateral surface of the first molding layer 400 may be spaced apart from the connection structure 210. A top surface of the first molding layer 400 may be coplanar with that of the connection structure 210 or those of the posts 212. In an implementation, the top surfaces of the posts 212 may be exposed on the top surface of the first molding layer 400. The first molding layer 400 may not cover a top surface of the first semiconductor chip 200. In this case, the top surface of the first molding layer 400 may be coplanar with that of the first semiconductor chip 200. The lateral surface of the first molding layer 400 may be vertically aligned with that of the first redistribution substrate 100. The first molding layer 400 may include a dielectric polymer, such as an epoxy molding compound (EMC).

The second redistribution substrate 300 may be on the first molding layer 400. The second redistribution substrate 300 may be in contact with the top surface of the first molding layer 400 and the top surfaces of the posts 212.

The second redistribution substrate 300 may include a plurality of second dielectric layers 310 that may be stacked on each other. FIG. 1 depicts that three second dielectric layers 310 may be stacked. The number of the second dielectric layers 310 stacked on the second redistribution substrate 300 may be variously changed if necessary. The second dielectric layer 310 may include an organic material, such as a photo-imageable dielectric (PID) material. The photo-imageable dielectric material may be a polymer. The photo-imageable dielectric material may include, e.g., photosensitive polyimide, polybenzoxazole, phenolic polymers, or benzocyclobutene polymers. FIG. 1 shows a boundary between the second dielectric layers 310. According to some embodiments, an indistinct interface may be between neighboring second dielectric layers 310.

The second dielectric layers 310 may be provided with second redistribution patterns 320 therein. The second redistribution patterns 320 may each have a second via part and a second line part that may be connected into a single unitary piece. The second line part may be a pattern for horizontal connection in the second redistribution substrate 300. The second via part may be a portion for vertical connection between the second redistribution patterns 320 in the second dielectric layers 310. The second line part may be on the second via part. The second line part and the second via part may be connected with no interface therebetween. The second line part may have a width greater than that of the second via part. In an implementation, each of the second redistribution patterns 320 may have a T shape when viewed in vertical section. In an implementation, the second via part may have a second via part upper width at an upper portion of the second via part and a second via part lower width at a lower portion of the second via part, and the second via part upper width may be greater than the second via part lower width. In greater detail, the second via part may have a width that decreases with distance from the top surface of the second via part. In an implementation, both the second via part upper width and the second via part lower width may be smaller than the width of the second line part.

The second line parts of the second redistribution patterns 320 may be positioned on top surfaces of the second dielectric layers 310. The second via parts of the second redistribution patterns 320 may penetrate the second dielectric layers 310 coupled to the second line parts of other second redistribution patterns 320 that underlie the second via parts of the second redistribution patterns 320. An uppermost one of the second redistribution patterns 320 may be exposed on a top surface of the second redistribution substrate 300. The uppermost second redistribution pattern 320 may correspond to a pad on which additional semiconductor chip or package may be mounted on the second redistribution substrate 300. A lowermost one of the second redistribution patterns 320 may be in contact with the top surfaces of the posts 212. The second redistribution patterns 320 may be connected to the connection structures 210. The second redistribution patterns 320 may be electrically connected to the first semiconductor chip 200 through the connection structures 210 and the first redistribution patterns 120.

The second redistribution patterns 320 may include a conductive material. In an implementation, the second redistribution patterns 320 may include copper (Cu). Seed patterns may be on bottom surfaces of the second redistribution patterns 320. In an implementation, the seed patterns may cover bottom surfaces and sidewalls of the second via parts included in corresponding second redistribution patterns 320, and may also cover bottom surfaces of the second line parts included in corresponding second redistribution patterns 320. The seed patterns may include a different material from that of the second redistribution patterns 320. In an implementation, the seed patterns may include an alloy including copper (Cu) or titanium (Ti). The second redistribution patterns 320 may further include a barrier layer that may prevent diffusion of materials included in the second redistribution patterns 320. The barrier layer may include titanium nitride (TiN) or tantalum nitride (TaN).

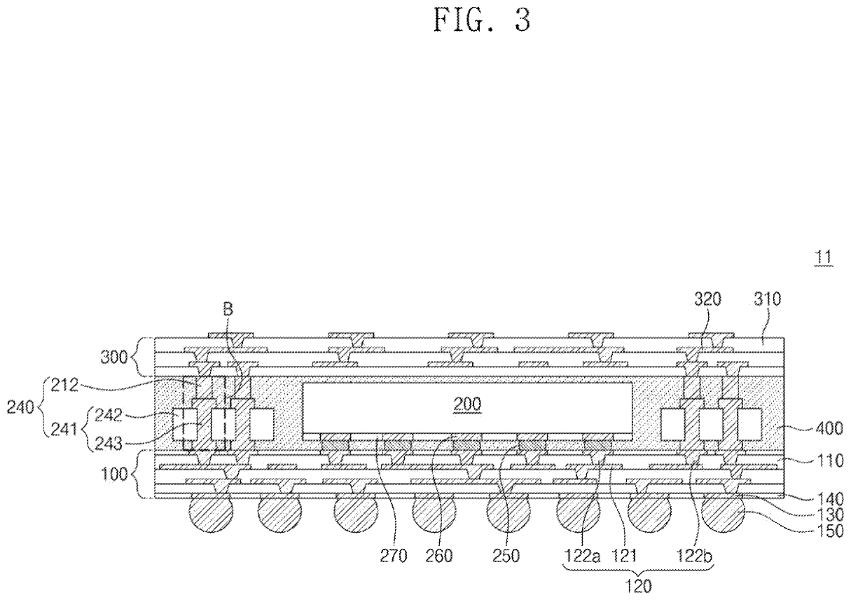

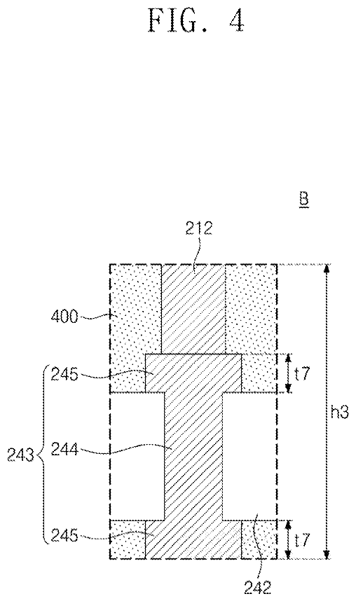

FIG. 3 is a cross-sectional view showing a semiconductor package. FIG. 4 is an enlarged view showing section B of FIG. 3. In the embodiment that follows, a repetitive description will be omitted, and the same reference numerals will be allocated to the same components.

Referring to FIGS. 3 and 4, a semiconductor package 11 may include a first redistribution substrate 100, a first semiconductor chip 200, a connection structure 240, a second redistribution substrate 300, and a first molding layer 400. The connection structure 240 may include a connection substrate 241, and posts 212. The connection structure 240 may have a height h3 of about 250 μm to about 350 μm.

Differently from the embodiment of FIGS. 1 and 2, the connection substrate 241 may not include any of the upper layer (see 223a of FIGS. 1 and 2), the lower layer (see 223b of FIGS. 1 and 2), and the second conductive patterns (see 224a and 224b of FIGS. 1 and 2). In an implementation, the connection substrate 241 may include a core layer 242 and a first conductive pattern 243. The core layer 242 may be substantially the same as the core layer 221 of the semiconductor package 10. A bottom surface of the first conductive pattern 243 may be in contact with a first redistribution pad 122b of the first redistribution substrate 100.

The first conductive pattern 243 may vertically penetrate the core layer 242. In an implementation, a first via 244 of the first conductive pattern 243 may vertically penetrate the core layer 242. The first via 244 may have a width that is constant from top to bottom surfaces of the core layer 242.

The first conductive pattern 243 may have first pads 245 on top and bottom surfaces of the first via 244. The first pads 245 may be in contact with the top and bottom surfaces of the first via 244. The first pads 245 may protrude from the core layer 242. The first pads 245 may be positioned on top and bottom surfaces of the core layer 242. The first pads 245 may be connected through the first via 244 to each other. An invisible interface may be between the first via 244 and the first pads 245. The first pads 245 may each have a thickness t7 of about 20 μm to about 40 μm.

Posts 212 may be on the first pads 245 on the top surface of the core layer 242. Each of the posts 212 may be in contact with a top surface of the first pad 245. The posts 212 may be spaced apart from the core layer 242. The posts 212 may not be in direct contact with the core layer 242. The posts 212 may be electrically connected to the first conductive patterns 243. The posts 212 may connect the connection substrate 241 to the second redistribution substrate 300. The posts 212 may each have a vertical height less than that of the connection substrate 241. The posts 212 may include a conductive material. The posts 212 may include, e.g., copper (Cu).

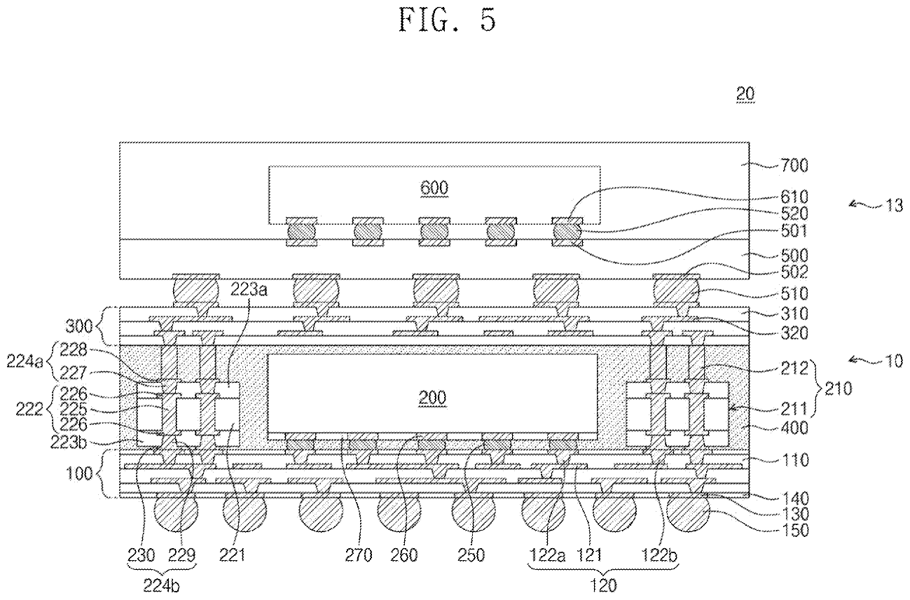

FIG. 5 is a cross-sectional view showing a semiconductor package. In the embodiment that follows, a repetitive description will be omitted, and the same reference numerals will be allocated to the same components.

Referring to FIG. 5, a semiconductor package 20 may include a first semiconductor package 10 and a second semiconductor package 13. The first semiconductor package 10 may be substantially the same as the semiconductor package 10 discussed with reference to FIG. 1. In some embodiments, the first semiconductor package 10 may be replaced with the semiconductor package 11 discussed with reference to FIG. 3.

The second semiconductor package 13 may include a package substrate 500, second connection terminals 510, a second semiconductor chip 600, second chip connection terminals 520, and a second molding layer 700.

The package substrate 500 may be on the second redistribution substrate 300. The package substrate 500 may be a printed circuit board (PCB). Alternatively, the package substrate 500 may be a redistribution substrate. The package substrate 500 may include a first substrate pad 501 on a top surface thereof and a second substrate pad 502 on a bottom surface thereof. The first substrate pad 501 may be exposed on the top surface of the package substrate 500. The second substrate pad 502 may be exposed on the bottom surface of the package substrate 500. The package substrate 500 may include a wiring pattern that electrically connects the first substrate pad 501 to the second substrate pad 502.

The second connection terminals 510 may be between the package substrate 500 and the second redistribution substrate 300. The second connection terminals 510 may be in contact with the second substrate pad 502 and the second redistribution patterns 320. The second connection terminals 510 may electrically connect the package substrate 500 to the second redistribution substrate 300.

The second semiconductor chip 600 may be on the package substrate 500. The second semiconductor chip 600 may have second chip pads 610 on a bottom surface of the second semiconductor chip 600. The second chip pads 610 may be electrically connected to an integrated circuit in the second semiconductor chip 600. The second chip pads 610 may be exposed on the bottom surface of the second semiconductor chip 600. The second chip pads 610 may include a conductive material. The second chip pads 610 may include, e.g., copper (Cu).

The second semiconductor chip 600 may be mounted on the package substrate 500. In an implementation, the second semiconductor chip 600 may be flip-chip mounted on the package substrate 500. The second chip connection terminals 520 may be between the second semiconductor chip 600 and the package substrate 500. The second chip connection terminals 520 may be between the second chip pads 610 of the second semiconductor chip 600 and the first substrate pads 501 of the package substrate 500. The second chip connection terminals 520 may be coupled to the second chip pads 610 of the second semiconductor chip 600 and the first substrate pads 501 of the package substrate 500. Therefore, the second semiconductor chip 600 may be electrically connected through the package substrate 500 to the first semiconductor package 10. The second chip connection terminals 520 may include a conductive material. The second chip connection terminals 520 may include, e.g., copper (Cu).

The second molding layer 700 may be on the package substrate 500. On the package substrate 500, the second molding layer 700 may encapsulate the second semiconductor chip 600. The second molding layer 700 may surround the second chip connection terminals 520 between the package substrate 500 and the second semiconductor chip 600. Alternatively, an underfill may be between the package substrate 500 and the second semiconductor chip 600. The second molding layer 700 may include a dielectric polymer, such as an epoxy molding compound (EMC).

In an example embodiment, redistribution substrates may be connected through a connection structure to each other. The connection structure may include a connection substrate and a post on the connection substrate. There may be a reduction in process step and manufacturing cost in a process in which the connection substrate is manufactured and then placed on the redistribution substrate to form the connection structure, compared to a process in which only a photoresist is used to form a copper pillar, and thus the semiconductor package may increase in productivity.

In addition, the connection structure including the connection substrate may be easy to adjust its height in fabrication process. An increase in height of the connection structure may induce an increase in thickness of a semiconductor chip, and thus the semiconductor chip may improve in thermal radiation properties. As a result, the semiconductor package may improve in reliability and thermal stability.

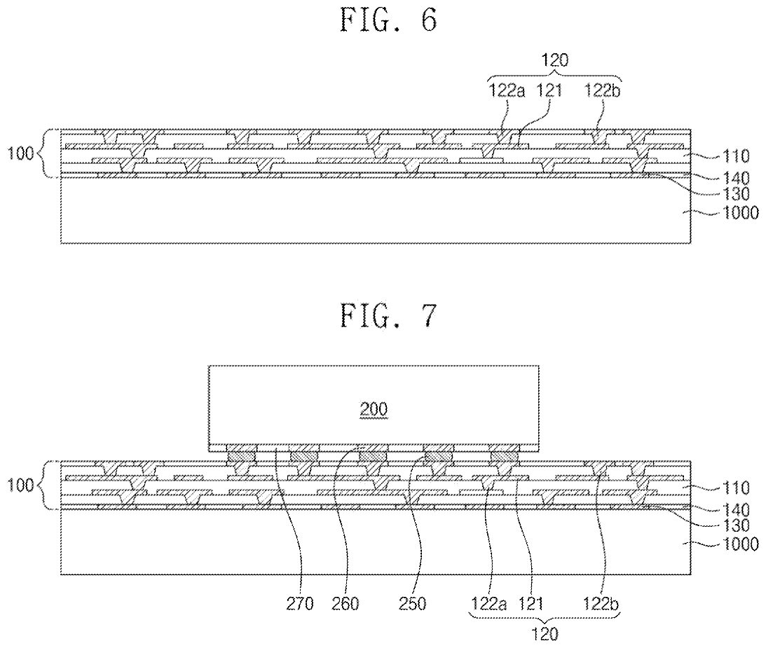

FIGS. 6 to 11 are cross-sectional views showing steps in a method of fabricating a semiconductor package. The same reference numerals may be allocated to the same components discussed above.

Referring to FIG. 6, a carrier substrate 1000 may be provided. The carrier substrate 1000 may be a dielectric substrate including glass or polymer, or may be a conductive substrate including metal. An adhesive member may be on a top surface of the carrier substrate 1000. In an implementation, the adhesive member may include a glue tape.

Substrate pads 130 may be on the carrier substrate 1000. The substrate pads 130 may be formed by an electroplating process. In an implementation, a substrate protection layer 140 may be formed on the carrier substrate 1000, and then openings may be formed in the substrate protection layer 140 to define regions where the substrate pads 130 may be formed. Afterwards, the electroplating process may be performed to allow a conductive material to fill the openings. The substrate protection layer 140 may surround the substrate pads 130. The substrate protection layer 140 may expose top surfaces of the substrate pads 130.

A first dielectric layer 110 may be on the substrate protection layer 140. In an implementation, a dielectric material may be coated on the substrate protection layer 140 to form the first dielectric layer 110. The dielectric material may include an organic material, such as a photo-imageable dielectric (PID) material. The photo-imageable dielectric material may be a polymer. The photo-imageable dielectric material may include, e.g., photosensitive polyimide, polybenzoxazole, phenolic polymers, or benzocyclobutene polymers.

The first dielectric layer 110 may include openings. A metal layer may fill the openings of the first dielectric layer 110 and may cover the first dielectric layer 110. The metal layer may include first redistribution patterns 120. The first redistribution patterns 120 may include first wiring patterns 121 and first redistribution pads 122a and 122b. The first redistribution pads 122a and 122b may be the first redistribution patterns 120 that may be exposed on an uppermost end of the first dielectric layer 110.

Before the first redistribution patterns 120 are formed, seed patterns may be conformally formed on a top surface of the first dielectric layer 110 and in the openings of the first dielectric layer 110. An electroplating process may be performed in which the seed patterns may be used as electrodes to form the first redistribution patterns 120. The first redistribution patterns 120 may be on the top surface of the first dielectric layer 110 and in the openings of the first dielectric layer 110, covering the seed patterns. Each of the first redistribution patterns 120 may each include a first via part and a first line part. The first via part may be in at least one corresponding opening of the first dielectric layer 110. The first line part may be on the first via part, and may extend onto the top surface of the first dielectric layer 110.

The formation of the first dielectric layer 110, the seed patterns, and the first redistribution patterns 120 may be repeatedly performed. Therefore, a first redistribution substrate 100 may include stacked first dielectric layers 110 and stacked first redistribution patterns 120.

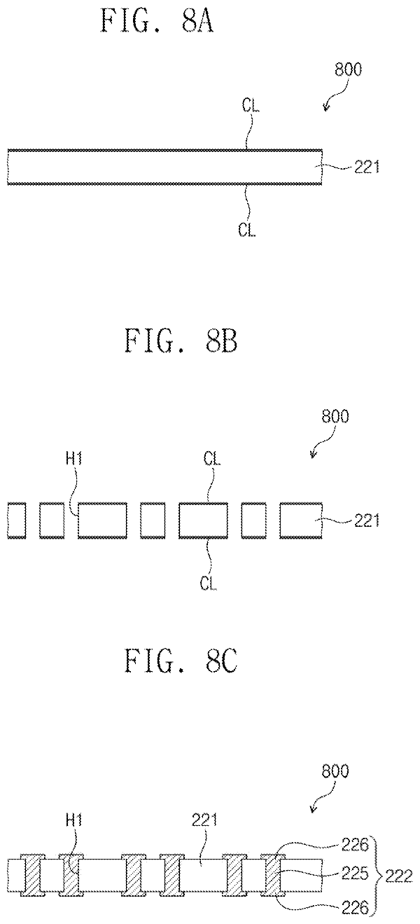

Referring to FIG. 7, a first semiconductor chip 200 may be on the first redistribution substrate 100. The first semiconductor chip 200 may be flip-chip mounted on the first redistribution substrate 100. The first semiconductor chip 200 may be mounted on the first redistribution substrate 100 through first chip connection terminals 250. In an implementation, the first chip connection terminals 250 may be on first chip pads 260 on a bottom surface of the first semiconductor chip 200, and then the first semiconductor chip 200 may be placed on the first redistribution substrate 100 to allow first redistribution pads 122a of the first redistribution substrate 100 to align with the first chip connection terminals 250 of the first semiconductor chip 200. Afterwards, the first chip connection terminals 250 may undergo a reflow process to allow the first chip connection terminals 250 to connect with the first chip pads 260 and the first redistribution pads 122a.

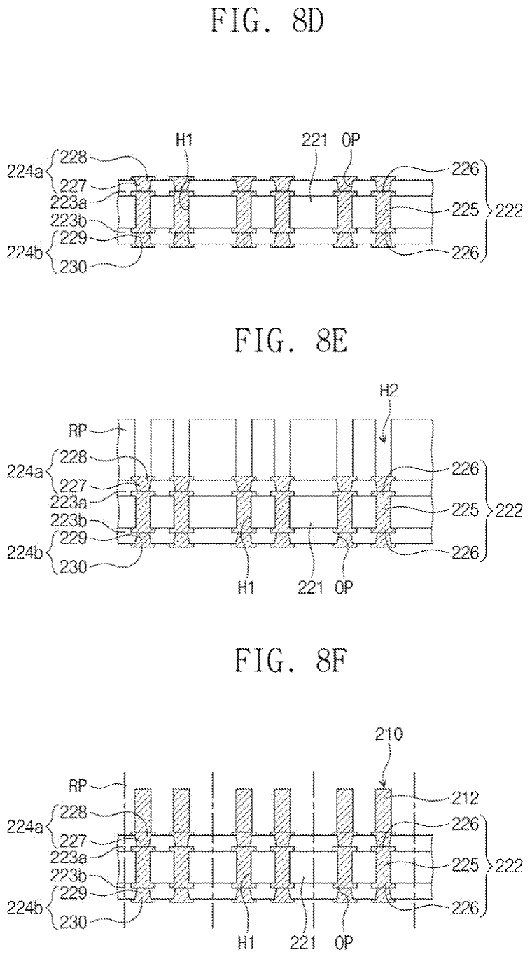

Subsequently, a connection structure may be manufactured. The following will describe a method of fabricating a connection structure. FIGS. 8A to 8F are cross-sectional views showing a method of fabricating a connection structure.

Referring to FIG. 8A, a substrate 800 may be provided. The substrate 800 may include a core layer 221 and metal layers CL. The metal layers CL may be on top and bottom surfaces of the core layer 221. In an implementation, the substrate 800 may have a stack structure in which the core layer 221 is between the metal layers CL. The core layer 221 may include a material substantially the same as that of the core layer 221 discussed with reference to FIG. 1. The metal layers CL may include copper (Cu). The substrate 800 may include, e.g., a copper clad lamination (CCL).

Referring to FIG. 8B, a first hole H1 may vertically penetrate the substrate 800. The first hole H1 may be formed by using a mechanical drill or a laser drill. The first hole H1 may connect top and bottom surfaces of the substrate 800 to each other. The first hole H1 may have a width that is constant from the top to bottom surfaces of the substrate 800.

Referring to FIG. 8C, a first conductive pattern 222 may fill the first hole H1. The first conductive pattern 222 may include a first via 225 that may vertically penetrate the core layer 221. The first conductive pattern 222 may be formed by a plating process. Afterwards, a patterning process may be performed to form first pads 226 on top and bottom surfaces of the first via 225. The first pads 226 may protrude from the core layer 221. The patterning process may remove the metal layers CL. A visible interface may be between the metal layer CL and the first pads 226.

Referring to FIG. 8D, an upper layer 223a may be on the top surface of the core layer 221. A lower layer 223b may be on the bottom surface of the core layer 221. The upper layer 223a and the lower layer 223b may cover the top surface of the core layer 221, the bottom surface of the core layer 221, and the first pads 226.

The upper layer 223a and the lower layer 223b may form openings OP. The openings OP may expose the first pads 226. The opening OP may have a width that decreases with distance from the core layer 221. A conductive layer may fill the openings OP and may cover the upper layer 223a and the lower layer 223b. Portions of the conductive layer filling the openings OP may constitute second vias 227 and 229. After the conductive layer is formed, the conductive layer may be patterned to form second pads 228 and 230. The second pads 228 and 230 may protrude from the upper layer 223a and the lower layer 223b.

Referring to FIG. 8E, a mask RP may be on the upper layer 223a. The mask RP may be patterned to form second holes H2 that expose second upper pads 228. Referring to FIG. 8F, posts 212 may fill the second holes H2. The posts 212 may be formed by a plating process performed in the second holes H2. The posts 212 may be on the second upper pads 228. Thereafter, the mask RP may be removed. The core layer 221, the upper layer 223a, and the lower layer 223b may be cut to form one connection structure 210.

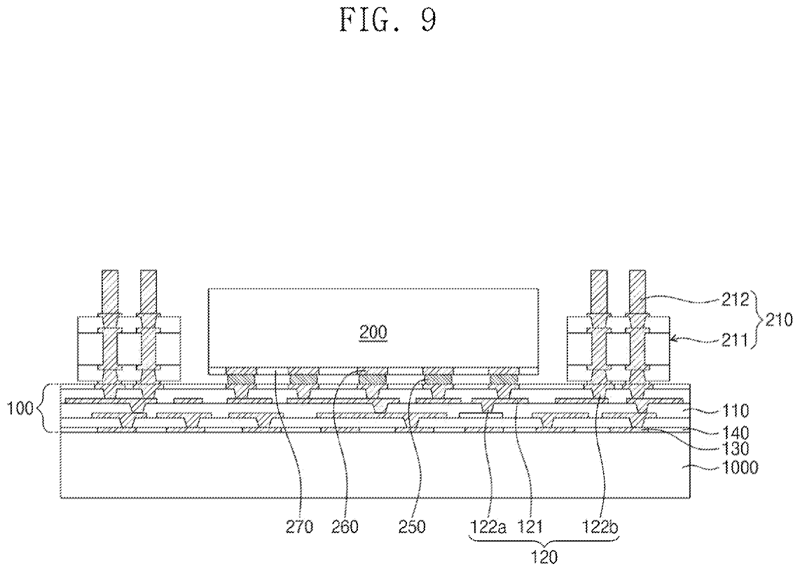

Referring to FIG. 9, on the resultant structure of FIG. 7, a connection structure 210 may be on the first redistribution substrate 100. The connection structure 210 may be on the first redistribution pad 122b. The connection structure 210 may be laterally spaced apart from the first semiconductor chip 200. The connection structure 210 may surround the first semiconductor chip 200. After the connection structure 210 is disposed on the first redistribution substrate 100, the first semiconductor chip 200 may be mounted.

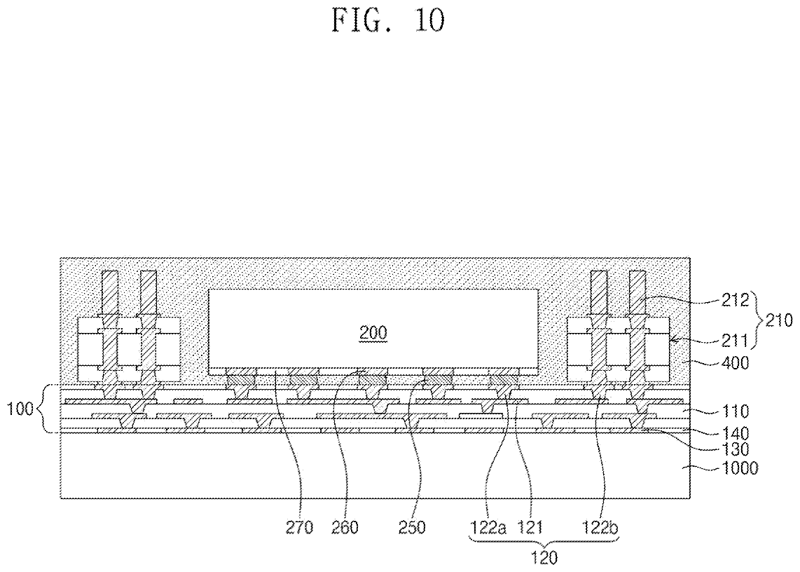

Referring to FIG. 10, a first molding layer 400 may be on the first redistribution substrate 100. The first molding layer 400 may cover the connection structure 210, the first semiconductor chip 200, and the top surface of the first redistribution substrate 100. In an implementation, a dielectric material may be coated on the first redistribution substrate 100 to encapsulate the first semiconductor chip 200 and the connection structure 210. The first molding layer 400 may surround the first chip connection terminals 250 between the first redistribution substrate 100 and the first semiconductor chip 200. The dielectric material may include a dielectric polymer, such as an epoxy molding compound (EMC).

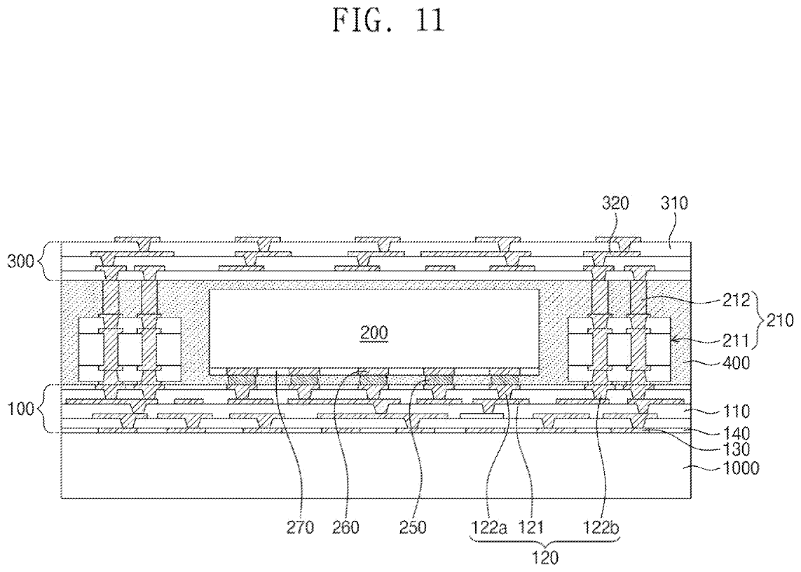

Referring to FIG. 11, a grinding process may be performed on the first molding layer 400. An upper portion of the first molding layer 400 may be removed through the grinding process. The grinding process may remove portions of the posts 212 together with the first molding layer 400. The grinding process may expose a top surface of the first semiconductor chip 200. The grinding process may include, e.g., a chemical mechanical polishing (CMP) process.

A second dielectric layer 310 may be on the first molding layer 400. In an implementation, a dielectric material may be coated on the first molding layer 400 to form the second dielectric layer 310. The dielectric material may include an organic material, such as a photo-imageable dielectric (PID) material. The photo-imageable dielectric material may be a polymer. The photo-imageable dielectric material may include, e.g., photosensitive polyimide, polybenzoxazole, phenolic polymers, or benzocyclobutene polymers.

The second dielectric layer 310 may be patterned to form openings. A metal layer may fill the openings of the second dielectric layer 310 and may cover the second dielectric layer 310. The metal layer may be patterned to form second redistribution patterns 320. Ones of the openings in the second dielectric layer 310 may expose top surfaces of the posts 212, and therefore the second redistribution patterns 320 may contact the top surfaces of the posts 212. An uppermost one of the second redistribution patterns 320 may be exposed on a top surface of the second redistribution substrate 300.

Before the second redistribution patterns 320 are formed, seed patterns may be conformally formed on a top surface of the second dielectric layer 310 and in the openings of the second dielectric layer 310. Portions of a lowermost seed pattern may be on the top surfaces of the posts 212. An electroplating process may be performed in which the seed patterns are used as electrodes to form the second redistribution patterns 320. The second redistribution patterns 320 may be on the top surface of the second dielectric layer 310 and in the openings of the second dielectric layer 310, covering the seed patterns. Each of the second redistribution patterns 320 may include a second via part and a second line part. The second via part may be in corresponding opening of the second dielectric layer 310. The second line part may be on the second via part, and may extend onto the top surface of the second dielectric layer 310.

The formation of the second dielectric layer 310, the seed patterns, and the second redistribution patterns 320 may be repeatedly performed. Therefore, a second redistribution substrate 300 may be constituted by stacked second dielectric layers 310 and stacked second redistribution patterns 320.

Referring back to FIG. 1, first connection terminals 150 may be on a bottom surface of the first redistribution substrate 100. The first connection terminals 150 may be on the substrate pads 130 on the bottom surface of the first redistribution substrate 100. The first connection terminals 150 may be laterally spaced apart from each other. A semiconductor package 10 may thus be fabricated.

A semiconductor package may include a connection structure that connects redistribution substrates to each other. A connection substrate of the connection structure may facilitate the connection structure to have an increased vertical height. It may thus be possible to mount a thick semiconductor chip in the semiconductor package and to easily discharge heat from a semiconductor chip. As a result, the semiconductor package may increase in thermal stability.

In addition, the semiconductor package including the connection substrate may be fabricated easier than a semiconductor package configured to include only a post instead of the connection substrate, and accordingly the semiconductor package formation process may increase in productivity.

By way of summation and review, a semiconductor including a connection structure is disclosed. A semiconductor package may be configured such that a semiconductor chip is mounted on a printed circuit board and bonding wires or bumps may be used to electrically connect the semiconductor chip to the printed circuit board. With the development of electronic industry, various studies have been conducted to improve reliability and durability of semiconductor packages. Some embodiments provide a semiconductor package whose thermal stability is improved. Some embodiments provide a semiconductor package whose productivity is increased.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package, comprising:
a first redistribution substrate;
a semiconductor chip on the first redistribution substrate;
a connection structure on the first redistribution substrate and spaced apart from the semiconductor chip, the connection structure including a connection substrate and a post on the connection substrate;
a second redistribution substrate on the semiconductor chip and the connection structure; and
a molding layer between the first redistribution substrate and the second redistribution substrate, the molding layer encapsulating the semiconductor chip and the connection structure,
wherein:
the connection substrate includes a conductive pattern that vertically penetrates the connection substrate,
the post is in contact with a top surface of the conductive pattern, and
a width of the post is less than a width of the connection substrate.

2. The semiconductor package as claimed in claim 1, wherein the connection substrate includes:
a core layer;
an upper layer that covers a top surface of the core layer; and
a lower layer that covers a bottom surface of the core layer, a lateral surface of the core layer, a lateral surface of the upper layer, and a lateral surface of the lower layer being vertically aligned with each other.

3. The semiconductor package as claimed in claim 2, wherein the conductive pattern includes:
a first conductive pattern that vertically penetrates the core layer of the connection substrate; and
a plurality of second conductive patterns that penetrate the upper layer and the lower layer of the connection substrate, the first conductive pattern connecting the plurality of second conductive patterns to each other.

4. The semiconductor package as claimed in claim 3, wherein the first conductive pattern has a width that is constant between the top surface and the bottom surface of the core layer of the connection substrate.

5. The semiconductor package as claimed in claim 3, wherein each of the plurality of second conductive patterns have a width that decreases with distance from the core layer of the connection substrate.

6. The semiconductor package as claimed in claim 1, wherein the conductive pattern includes:
a via that penetrates the connection substrate; and
an upper pad and a lower pad that protrude from the connection substrate, the post being in contact with a top surface of the upper pad.

7. The semiconductor package as claimed in claim 1, wherein the connection substrate is spaced apart from a lateral surface of the molding layer.

8. The semiconductor package as claimed in claim 1, wherein:
a top surface of the post is coplanar with a top surface of the molding layer, and the top surface of the post and the top surface of the molding layer are in contact with a bottom surface of the second redistribution substrate.

9. A semiconductor package, comprising:
a first redistribution substrate;
a semiconductor chip on the first redistribution substrate;
a second redistribution substrate on the semiconductor chip;
a connection structure spaced apart from the semiconductor chip and connecting the first redistribution substrate and the second redistribution substrate to each other, the connection structure including a connection substrate and a post on the connection substrate; and
a molding layer between the first redistribution substrate and the second redistribution substrate, the molding layer surrounding the post and the semiconductor chip,
wherein the connection substrate includes:
a core layer;
a first conductive pattern that vertically penetrates the core layer;
an upper layer that covers a top surface of the core layer;
a lower layer that covers a bottom surface of the core layer; and
a plurality of second conductive patterns that penetrate the upper layer and the lower layer, the plurality of second conductive patterns being connected to the first conductive pattern, and each of the plurality of second conductive patterns having a width that decreases with distance from the core layer.

10. The semiconductor package as claimed in claim 9, wherein the post is spaced apart from the upper layer of the connection substrate.

11. The semiconductor package as claimed in claim 9, wherein a width of the post is less than a width of the connection substrate.

12. The semiconductor package as claimed in claim 9, wherein the first conductive pattern has a width that is constant between the top surface and the bottom surface of the core layer of the connection substrate.

13. The semiconductor package as claimed in claim 9, wherein a lateral surface of the core layer of the connection substrate, a lateral surface of the upper layer of the connection substrate, and a lateral surface of the lower layer of the connection substrate are vertically aligned with each other.

14. The semiconductor package as claimed in claim 9, wherein the second conductive pattern has a plurality of pads that protrude from a top surface and a bottom surface of the connection substrate.

15. The semiconductor package as claimed in claim 9, wherein the post is in contact with a top surface of one of the plurality of second conductive patterns that penetrates the upper layer of the connection substrate.

16. The semiconductor package as claimed in claim 9, wherein the connection substrate is spaced apart from a lateral surface of the molding layer.

17. The semiconductor package as claimed in claim 9, wherein:
a top surface of the post is coplanar with a top surface of the molding layer, and the top surface of the post and the top surface of the molding layer are in contact with a bottom surface of the second redistribution substrate.

18. A semiconductor package, comprising:
a first redistribution substrate;
a first semiconductor chip mounted on the first redistribution substrate;
a connection substrate on the first redistribution substrate and surrounding the first semiconductor chip;
a post on the connection substrate;
a molding layer that surrounds the first semiconductor chip, the post, and the connection substrate; and
a second redistribution substrate on the molding layer,
wherein:
the connection substrate includes:
a core layer;
an upper layer on a top surface of the core layer;
a lower layer on a bottom surface of the core layer;
a first conductive pattern that vertically penetrates the core layer; and
a plurality of second conductive patterns that correspondingly penetrate the upper layer and the lower layer,
a lateral surface of the core layer, a lateral surface of the upper layer, and a lateral surface of the lower layer are vertically aligned with each other, and
a width of the first conductive pattern is constant between the top surface and the bottom surface of the core layer.

19. The semiconductor package as claimed in claim 18, wherein each second conductive pattern of the plurality of second conductive patterns has a width that decreases with distance from the core layer of the connection substrate.

20. The semiconductor package as claimed in claim 18, wherein a width of the post is less than a width of the connection substrate.
